(19) United States
(12) Patent Application Publication
(10) Pub. No.: US 2026/0208672 A1
(43) Pub. Date: Jul. 23, 2026

(54) MICRO-LEDS FOR VEHICLE INTERIOR LIGHT

(71) Applicant: VueReal Inc., Waterloo (CA)

(72) Inventors: Gholamreza CHAJI, Waterloo (CA); John CRONIN, Jericho, VT (US)

(73) Assignee: VueReal Inc., Waterloo, ON (CA)

(21) Appl. No.: 19/142,277

(22) PCT Filed: Dec. 22, 2023
(86) PCT No.: PCT/CA2023/051748

§ 371 Date: Jun. 23, 2025

Related U.S. Application Data
(60) Provisional application No. 63/477,044, filed on Dec. 23, 2022.

(51) Int. Cl. B60Q 3/60; B60Q 3/70

(52) U.S. Cl. CPC B60Q 3/60; B60Q 3/70

(57) ABSTRACT

A Micro-LED-based vehicle interior light. Micro-LEDs may be arranged in a panel with density to create the same or similar intensity light as existing interior light designs or to conform with legal requirements. These Micro-LED interior lights may allow for cheaper, more energy efficient, smaller, and/or more customizable interior lights.

### BACKGROUND AND FIELD OF THE DISCLOSURE

The present disclosure is generally related to micro-LEDs and their use in automotive applications.

Vehicle interior lighting is often very simple, with one or two light sources illuminating the entirety of the car, which can be a dangerous distraction to the driver.

Vehicle interior lights cannot convey complex information. A driver may be able to tell that a glove box is open if the glove box light is on but cannot provide much more information without complex blinking codes, which the driver would have to memorize.

Interior lighting information may be readily available to the driver due to their dashboard display, but passengers may rely on the driver to tell them which door is ajar or which seatbelt is not secure.

Traditional lighting leaves much to be desired when looking for new vehicle lighting applications. For example, creating a light-augmented music system is difficult when the lights are only one color and one intensity.

### SUMMARY

The present invention relates to a method to use Micro-LEDs in a vehicle interior light, the method comprising, having a Micro-LED panel comprised of one or more Micro-LED tiles of Micro-LEDs, having a substrate to which the Micro-LED tile is bound and having a connector which allows electronics of the Micro LED panel to integrate with a vehicle, wherein the Micro-LED panel performs a function of a vehicle interior light.

### DESCRIPTIONS OF THE DRAWINGS

FIG. 1: Illustrates an integration of a transferred microdevice with an electro-optical thin film device in a hybrid structure, according to an embodiment.

FIG. 2: Illustrates a Micro-LED panel for interior light, according to an embodiment.

FIG. 3: Illustrates a Micro-LED panel for an interior light that is colored and/or textured based on the vehicle component it is attached to, according to an embodiment.

FIG. 4: Illustrates Micro-LEDs embedded in internal components of a vehicle where colors can be adjusted based on circumstances (dimmers for night driving, bright for reading at night, colored for aesthetic, etc.), according to an embodiment.

FIG. 5: Illustrates a mirror with embedded Micro-LEDs, according to an embodiment.

FIG. 6: Illustrates a Micro-LED panel for an interior light combined with non-Micro-LED light sources, according to an embodiment.

FIG. 7: Illustrates a Micro-LED panel for an interior light integrated into the fabric, according to an embodiment.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples. The present disclosure discloses, structure, system and methods related to Micro-LEDs in exterior or interior aspects of vehicle lights.

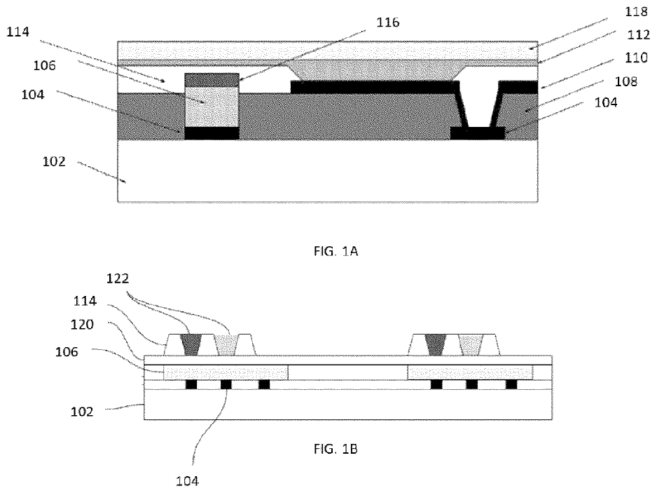

FIG. 1A shows an example of integrating a transferred microdevice 106 with an electro-optical thin film device 112 in a hybrid structure. This is an example of an integrated micro-led tile that is later picked and placed into an array of tiles. It should be obvious to those in the art there are many ways to create micro-led tiles and integrate them in an array of tiles, as per US20160218143A1-Microdevice integration into system substrate. A receiver substrate 102 and contact pads 104 upon which the microdevice 106 arrays are transferred and into which the thin film electro-optical device is integrated in a number of hybrid structure embodiments. Microdevice 106 may be transferred and bonded to the bonding pad 104 of the receiver substrate 100. In one case, a dielectric layer 108 is formed over the substrate 102 to cover the exposed electrodes and conductive layers. Lithography and etching may be used to pattern the dielectric layer 108. Conductive layer 110 is then deposited and patterned to form the bottom electrode of the thin film electro-optical device 112. If there is no risk of unwanted coupling between bottom electrode 110 and other conductive layers in the receiver substrate, the dielectric layer 108 may be eliminated. However, this dielectric layer can also act as a planarization layer to offer better fabrication of electro-optical devices 112. A bank layer 114 is deposited on the substrate 102 to cover the edges of the electrode 110 and the microdevice 106. Thin film electro-optical device 112 is then formed over this structure. Organic LED (OLED) devices are an example of a thin film electro-optical device that may be formed using different techniques such, as but not limited to shadow mask, lithography, and printing patterning. Finally, the top electrode 118 of the electro-optical thin film device 112 is deposited and patterned if needed. In an embodiment where the microdevices' 106 thickness is significantly high, cracks or other structural problems may occur within the bottom electrode 110. In these embodiments, a planarization layer may be used in conjunction with or without the dielectric layer 108 to address this issue. In another embodiment, the microdevice 106 can have a device electrode 116. This electrode can be common between other microdevices 106 in the system substrate. In this case, the planarization layer (if present) and/or bank structure 114 covers the electrode 116 to avoid any shorts between the electro-optical device 112 and device electrode 116.

FIG. 1B illustrates structures where the device is shared between a few pixels (or sub-pixels) after post-processing to deposit a common electrode and color conversion layers. Here the microdevice 106 is not fully patterned, but the horizontal condition is engineered so that the contacts 104 define the area allocated to each pixel. The system substrate 102 with contact pads 104 and a donor substrate with microdevices 106. After the microdevices 106 are transferred to system substrate 102, one can do post-processing, such as depositing common electrode 120, color conversion layers 122, color filters, and so on. However, the methods described in this disclosure and other possible methods can be used. It is possible to add the color conversion layers as described into pixel (or sub-pixel) active areas after forming the active area. This can offer a higher fill factor and higher performance and avoid color leaking from the side pixel (or sub-pixel) if the active area of the pixel (or sub-pixel) is covered by reflective layers. The microdevices 106 are grown on a buffer/sacrificial layer in another embodiment.

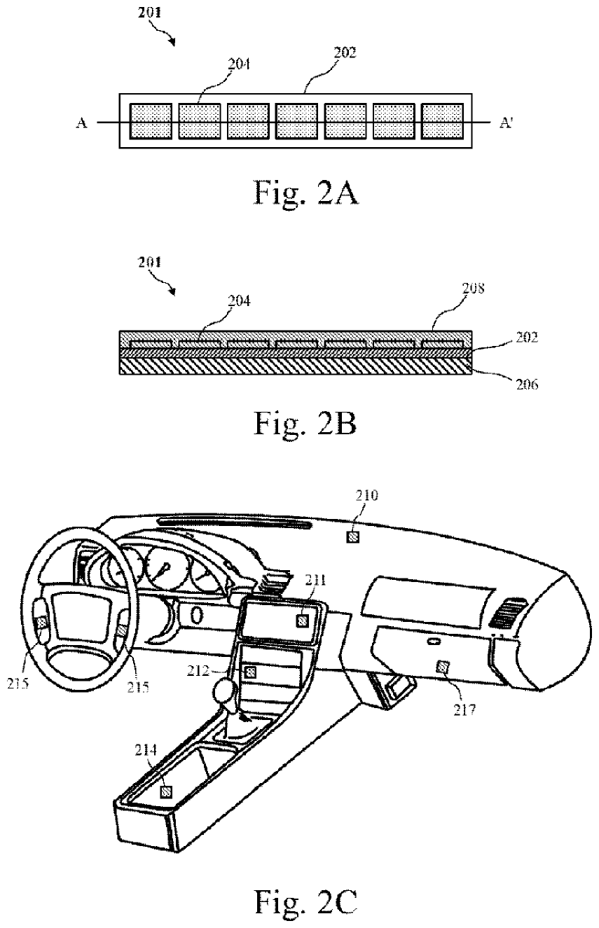

FIG. 2A displays a Micro-LED panel for interior light. FIG. 2B displays a cross-section of the Micro-LED panel of FIG. 2A along the line A-A′. FIG. 2C displays possible locations for the Micro-LED panel of FIG. 2A within a vehicle. Element 201 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing interior lights. The panel may use RGB Micro-LEDs. The intensity and color of the light from the Micro-LED panel may be programmable and change based on input. Element 202 may be an adhesive strip which may allow the Micro-LED panel to adhere, or otherwise connect to, the vehicle. Element 204 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 206 may be an adhesive strip which may allow the Micro-LED panel to adhere, or otherwise connect to, the vehicle. Element 208 may be a protective layer. The protective layer may protect from environmental and/or vibrational damage. The protective layer may be made of glass, epoxy, plastic, metal, other protective materials, or any combination of protective materials. The protective layer may be hermetically sealed. Element 210 may be the Micro-LED panel of FIG. 2A on a vehicle dashboard. The Micro-LED panel in this location may display information, project information onto the windshield, provide lighting, or contribute to the ambiance of the inside of the vehicle. Element 211 may be the Micro-LED panel of FIG. 2A as a vehicle information panel. The Micro-LED panel in this location may display information, allow the driver or passengers of the vehicle to choose features such as GPS or music, otherwise act as a user interface for the vehicle's computer, provide lighting, or contribute to the ambiance of the inside of the vehicle. Element 212 may be the Micro-LED panel of FIG. 2A on a trim piece of the vehicle. The Micro-LED panel in this location may provide lighting or contribute to the ambiance of the inside of the vehicle. Element 214 may be the Micro-LED panel of FIG. 2A in a middle storage compartment of a vehicle. The Micro-LED panel in this location may provide lighting or contribute to the ambiance of the inside of the vehicle. The Micro-LED panel in this location may be configured to not interfere with the passenger side airbag. Element 214 may be the Micro-LED panel of FIG. 2A in a center cupholder or tray. The Micro-LED panel in this location may provide lighting or contribute to the ambiance of the inside of the vehicle. Element 215 may be the Micro-LED panel of FIG. 2A on the steering wheel of a vehicle. The Micro-LED panel in this location may display information to the driver, provide lighting, or contribute to the ambiance of the inside of the vehicle. The Micro-LED panel in this location may be configured to not interfere with the driver's airbag. Element 217 may be the Micro-LED panel of FIG. 2A on the passenger side front dashboard. The Micro-LED panel in this location may display information, act as a user interface for the passenger, provide lighting, or contribute to the ambiance of the inside of the vehicle. Element 217 may be the Micro-LED panel of FIG. 2A in the glove box of a vehicle. The Micro-LED panel in this location may provide lighting or contribute to the ambiance of the inside of the vehicle. This Micro-LED panel may be inside the glove box and active when the glove box is open. The Micro-LED panel may be smaller than a typical interior light bulb, reducing the space required for interior lights. While the initial costs of Micro-LED interior lights may be more than traditional interior lights, costs may be saved in other areas, such as replacement and energy costs. Micro-LEDs are more efficient than traditional interior lights, producing less heat and wasting less energy. Because of the reduced required volume, Micro-LED interior lights may be lighter than their traditional counterparts. The replacement costs for Micro-LED interior lights may be less than other interior lights due to the small size of the Micro-LED panel, meaning replacement is likely to be less invasive and may be easy enough to do without vehicle maintenance expertise.

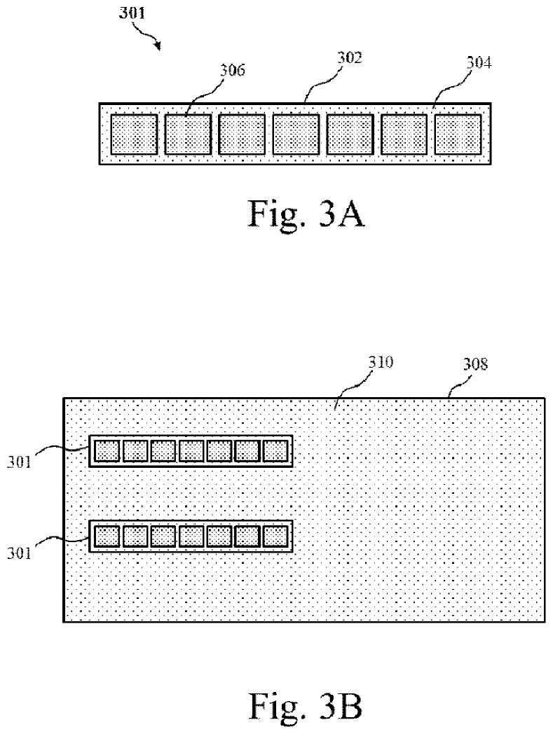

FIG. 3 displays a Micro-LED panel for an interior light-colored and/or textured based on the vehicle component it is attached to. Element 301 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing interior lights. The panel may use RGB Micro-LEDs. The light intensity from the Micro-LED panel may be programable and change based on input. Element 302 may be an adhesive strip which may allow the Micro-LED panel to adhere, or otherwise connect to, the vehicle. Element 304 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. The substrate may be colored and/or textured to match the color and/or texture of the component of the vehicle it is attached to or will be attached to. For example, the substrate may be textured to look like white leather if the Micro-LED panel is attached to white leather upholstery. Element 306 may be the first type of Micro-LED tile comprised of multiple Micro-LEDs. For example, these Micro-LED tiles may work as break lights and be colored red. Element 308 may be the interior component of the vehicle to which the Micro-LED panel is attached. Examples of interior components include dashboards, cupholders, door handles, drive shafts, seats, seatbelts, etc. The Micro-LED panel may enhance the vehicle's interior by increasing visibility, providing information to the driver or passengers, or adding to the overall ambiance inside the vehicle. Micro-LEDs can provide more information on a component that a regular LED or bulb would be able to because each Micro-LED has the functionality of a single larger LED. Element 310 may be a section material of the interior component of the vehicle, such as a patch of fabric or leather, or a panel of glass or plastic.

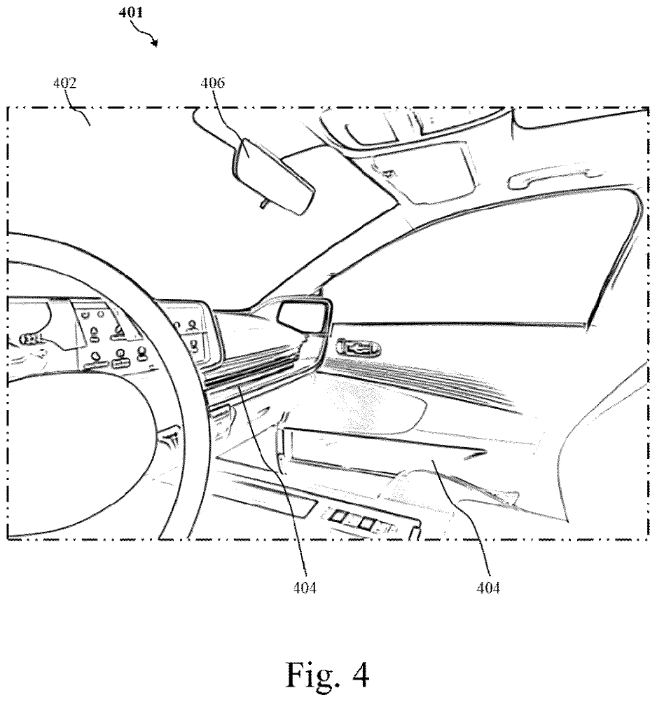

FIG. 4 displays Micro-LEDs embedded in internal components of a vehicle where colors can be adjusted to base on circumstances (dimmers for night driving, bright for reading at night, colored for aesthetics, etc.) Element 401 may be a vehicle interior with a network of integrated Micro-LEDs. The Micro-LEDs may be coordinated such that the color, brightness, state, etc., of each Micro-LED or group of Micro-LEDs, is set by one central computer system. For example, the computer may set the network of integrated Micro-LEDs to “night mode,” which may dim or turn off all of the Micro-LEDs except the ones that display essential information such as speed, gear, gas level, etc. The user may select and customize modes via a user interface inside the vehicle or by connecting to the vehicle's computer, for example, via NFC. The Micro-LED network may be configured to synchronize with music playing over the vehicle's audio system. Element 402 may be a windshield with embedded Micro-LEDs. The Micro-LEDs may color, tint, darken, or otherwise alter the view through the windshield. The Micro-LEDs may also display information directly on the windshield. The Micro-LEDs may be programmed not to distract the driver when driving and may only be active when the car is parked. These Micro-LEDs may be used for visibility and contribute to the ambiance within the vehicle. Element 404 may have accessories with embedded Micro-LEDs, such as cupholders, door compartments, armrests, etc. These Micro-LEDs may be used for visibility and contribute to the ambiance within the vehicle. Element 408 may trim with embedded Micro-LEDs. These Micro-LEDs may be used for visibility and contribute to the ambiance within the vehicle. Element 406 may be a mirror with embedded Micro-LEDs. This may be the rearview and/or side mirrors. The Micro-LEDs may color, tint, darken, or otherwise alter the view through the mirror. The Micro-LEDs may be able to display information such as warning signals, temperature, direction, etc., directly on the mirrors. The Micro-LEDs may show video from a camera. For example, the rearview mirror may contain a video view from a rearview camera on the back of the vehicle. These Micro-LEDs may be used for visibility and contribute to the ambiance within the vehicle. The Micro-LED panel may enhance the vehicle's interior by increasing visibility, providing information to the driver or passengers, or adding to the overall ambiance inside the vehicle. Micro-LEDs can provide more information on a component than a regular LED or bulb would be able to because each Micro-LED has the functionality of a single larger LED. Further, bulbs and large LEDs cannot be placed inside transparent components such as mirrors and windows without some obstruction of the view, but Micro-LEDs can be added to transparent material without significantly increasing the opacity.

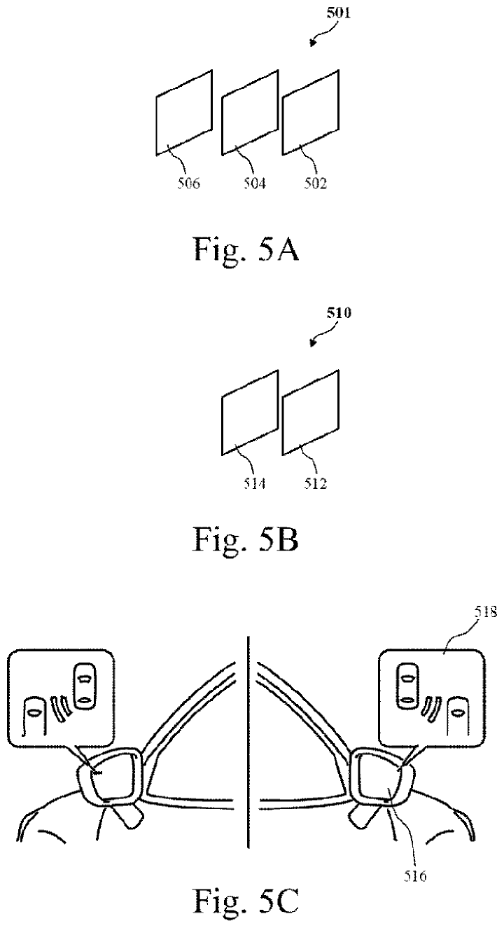

FIG. 5A displays a mirror with embedded Micro-LEDs. FIG. 5B displays another embodiment of the mirror with embedded Micro-LEDs. FIG. 5C displays the mirror of FIG. 5A. or FIG. 5B as vehicle side view mirrors. Element 501 may be a Micro-LED mirror comprising a Micro-LED panel, one-directional reflective layer, and front glass. Light incoming to the reflective layer through the front glass is reflected, while light from the Micro-LED panel passes through. An observer can see both what is reflected by the mirror and light from the Micro-LED panel. Element 502 may be front glass that protects the reflective layer while allowing light through. This may be glass, plexiglass, or other protective and transparent material. Element 504 may be a one-directional reflective layer that allows light to pass through from one direction but reflects light from the other direction. The one-directional reflective layer need not be fully reflective or transparent from either direction, such as a two-way mirror if the overall visual effect is the same. The one-directional reflective layer may be made from a thin and almost-transparent layer of metal or some other reflective material, creating a mirrored surface that reflects some light and is penetrated by the rest. Element 506 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing interior lights. The panel may use RGB Micro-LEDs. The light intensity from the Micro-LED panel may be programable and change based on input. Element 510 may be a Micro-LED mirror where the Micro-LEDs are placed onto a reflective substrate, eliminating the need for a one-way reflective layer. Element 512 may be a Micro-LED panel comprising one or more tiles containing multiple Micro-LEDs on or in a reflective surface. The Micro-LED tiles may be embedded or integrated with the reflective surface. Multiple small Micro-LED tiles can be integrated together into a larger flat plate. The panel may contain Micro-LEDs in the density to create the same light as the existing interior lights. The panel may use RGB Micro-LEDs. The light intensity from the Micro-LED panel may be programable and change based on input. Element 514 may be a support panel that may serve multiple functions such as adhering the Micro-LED panel to the vehicle, housing electronic components, connecting to the vehicle's electronic components, etc. Element 516 may be a vehicle's side view mirror using the Micro-LED mirror of FIG. 5A or FIG. 5B. Element 518 may be an example of a hazard symbol which may be displayed directly on the side view mirror via the Micro-LEDs. The Micro-LEDs may be able to display various different symbols to warn or inform the driver. The Micro-LED panel may also be able to display the video feed from a camera. For example, the side view mirror may also include a small, windowed view from a rear side camera to extend the driver's range of vision. Micro-LED mirrors may increase the amount of information a driver can see in their side view or rearview mirrors. This may lead to fewer collisions due to blind spots in the driver's field of view. The Micro-LED mirrors may also serve other functions while the car is not moving, such as lighting or ambiance.

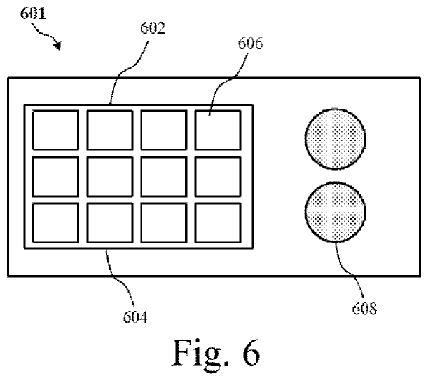

FIG. 6 displays a Micro-LED panel for an interior light combined with non-Micro-LED light sources. Element 601 may be a hybrid lighting system that includes Micro-LEDs and non-Micro-LED light sources such as LEDs, MiniLEDs, fluorescent bulbs, incandescent bulbs, natural lighting, etc. The Micro-LEDs and other light sources may be coordinated by a controller or may be controlled independently of each other. Element 602 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing interior lights. The panel may use RGB Micro-LEDs or Blue Micro-LEDs with Phosphorus to get white light. Element 604 may be an adhesive strip which may allow the Micro-LED panel to adhere, or otherwise connect to, the vehicle. Element 606 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 608 may be a non-Micro-LED-based light source such as an LED, Mini-LED, fluorescent bulb, incandescent bulb, natural lighting, or some other light source that does not use Micro-LED technology. Micro-LEDs may enhance the vehicle's interior by increasing visibility, providing information to the driver or passengers, or adding to the overall ambiance inside the vehicle. Micro-LEDs can provide more information on a component than regular LEDs or bulbs would be able to because each Micro-LED has the functionality of a single larger LED. Further, bulbs and large LEDs cannot be placed inside transparent components such as mirrors and windows without some obstruction of the view, but Micro-LEDs can be added to transparent material without significantly increasing the opacity. A combination of Micro-LEDs and traditional lighting may capture the benefits of both.

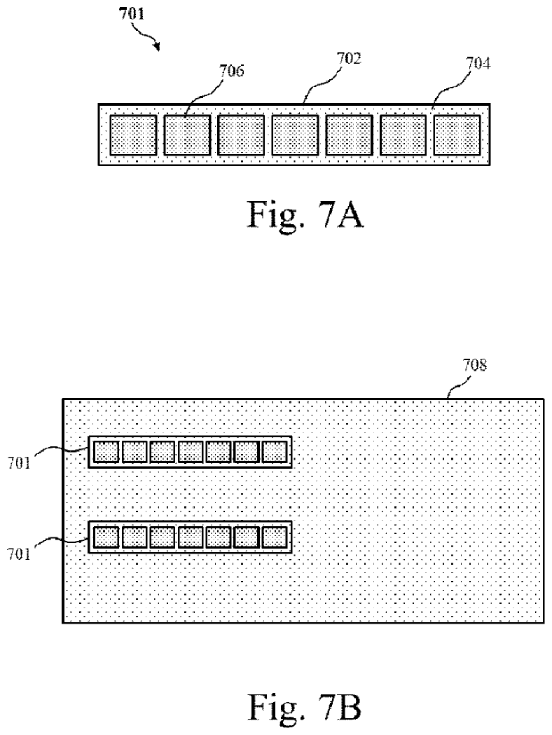

FIG. 7A displays a Micro-LED panel for an interior light and FIG. 7B displays the Micro-LED panel integrated into fabric. Element 701 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing interior lights. The panel may use RGB Micro-LEDs. The light intensity from the Micro-LED panel may be programable and change based on input. Element 702 may be an adhesive strip which may allow the Micro-LED panel to adhere, or otherwise connect to, the vehicle. Element 704 may be a substrate to which the Micro-LED tiles may be bound. The substrate may be silicon, glass, sapphire, any other substrate known in the art, any material to which Micro-LED tiles can be bound, or any combination of these materials. The substrate may be fabric or bound or otherwise adhered to the fabric. The substrate may have a similar flexibility to the fabric. The substrate may further house or be bound to electronics which connect to the Micro-LEDs. These electronics may be contained within the substrate, tunnel through the substrate to reach the Micro-LEDs, or use the substrate as part of the circuit. The substrate may be colored and/or textured to match the color and/or texture of the component of the vehicle it is attached to or will be attached to. For example, the substrate may be textured to look like white leather if the Micro-LED panel is attached to white leather upholstery. Element 706 may be the first type of Micro-LED tile comprised of multiple Micro-LEDs. For example, these Micro-LED tiles may work as break lights and be colored red. Element 708 may be the fabric component of the vehicle to which the Micro-LED panel is attached. Examples of fabric components, are seats, floor mats, fabric upholstery, etc. The Micro-LED panel may enhance the vehicle's interior by increasing visibility, providing information to the driver or passengers, or adding to the overall ambiance inside the vehicle. Micro-LEDs can provide more information on a component than a regular LED or bulb would be able to because each Micro-LED has the functionality of a single larger LED.

The functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

1. A method to use Micro-LEDs in a vehicle interior light, the method comprising:
having a Micro-LED panel comprised of one or more Micro-LED tiles of Micro-LEDs;
having a substrate to which the Micro-LED tile is bound; and
having a connector which allows electronics of the Micro LED panel to integrate with a vehicle,
wherein the Micro-LED panel performs a function of a vehicle interior light.

2. The method of claim 1, wherein multiple small Micro-LED tiles are integrated together into a larger flat plate.

3. The method of claim 2, wherein the panel contains Micro-LEDs in a density to enable creating a same light as conventional LED and non LED interior lights.

4. The method of claim 2, wherein an intensity and a color of the light from the Micro-LED panel may be programmable and change based on input.

5. The method of claim 2, wherein the panel uses RGB Micro-LEDs.

6. The method of claim 2, wherein the substrate is one of silicon, glass, sapphire, or any material to which Micro-LED tiles are bound or any combination of these materials.

7. The method of claim 2, wherein the substrate further houses or is bound to electronics which connects to the Micro-LEDs.

8. The method of claim 1, wherein the connector allows electronics of the panel to connect to the electronics system of a vehicle wherein further the electronics are contained within the substrate, tunnel through the substrate to reach the Micro-LEDs, or use the substrate as part of a circuit.

9. The method of claim 1, wherein there is a protective layer protecting from environmental and/or vibrational damage and wherein further the protective layer is either made of glass, epoxy, plastic, metal or any combination of protective materials and wherein further the protective layer is hermetically sealed.

10. The method of claim 1, wherein an adhesive strip allows the Micro-LED panel to adhere, or otherwise connect to the vehicle
